(19) United States
(12) Patent Application Publication
(10) Pub. No.: US 2016/0209448 A1
(43) Pub. Date: Jul. 21, 2016

(54) Voltage Detector Safety Glove

(71) Applicants: Robert H. Currie, Conroe, TX (US); Geoffrey W. Smith, Alvin, TX (US)

(72) Inventors: Robert H. Currie, Conroe, TX (US); Geoffrey W. Smith, Alvin, TX (US)

(21) Appl. No.: 14/598,957

(22) Filed: Jan. 16, 2015

(51) Int. Cl. G01R 19/155; G08B 21/02

(52) U.S. Cl. CPC G01R 19/155; G08B 21/02

(57) ABSTRACT

A safety glove for detecting the presence of a voltage has a pocket for receiving a voltage detector. An antenna or probe of the voltage detector may extend to a peripheral portion of the glove and may be covered by a piece of material. The voltage detector may be a non-contact type voltage detector sized to fit within the pocket.

### BACKGROUND OF INVENTION

1. Field of the Invention

This invention relates to a safety glove for carrying a hand held, non-contact, voltage tester of the type commonly used to detect the presence of voltage in areas such as power outlets in homes or business places. The safety glove can also be employed in any environment where a voltage can be detected to warn workers of the presence of an unintended voltage for example, in plumbing installations.

2. Description of Related Art

Devices commonly known as non-contact voltage testers are used to detect a voltage present at power outlets or plugs in homes or businesses. See for example U.S. Pat. Nos. 5,877,618 and 5,103,165, the entire contents of which are expressly incorporated herein by reference thereto. The device is normally hand held and positioned in close proximity to a power outlet having a plug-in type connector. If a voltage is detected, an indicator device such as a light and/or an audible sound is activated. With such a device it is possible for the user to get an unintended electrical shock should the user's hand come too close to the plug-in connector or too close to an unknown voltage source as sometimes occurs in construction areas. U.S. Pat. No. 7,295,130 discloses a non-contact voltage device in combination with a handheld tool.

### BRIEF SUMMARY OF THE INVENTION

This invention is directed to a work glove having a pocket for containing a non-contact voltage detector. In one embodiment a non-contact voltage detector is positioned within a pocket provided on a workman's type glove. The antenna of the voltage tester is extended to an extremity of one of the fingers of the glove. The antenna may be covered by a piece of material or may extend through a channel formed in the glove. The voltage detector may include a replaceable battery and may have alarms such as light and or audible beeps.

### BRIEF DESCRIPTION OF THE SEVERAL VIEWS OF THE DRAWING(S)

FIG. 1 is a top view of a glove according to an embodiment of the invention.

FIG. 2 is a cross-sectional view taken along line 2-2 of FIG. 1.

FIG. 3 is a cross-sectional view taken along line 3-3 of FIG. 1.

### DETAILED DESCRIPTION OF THE INVENTION

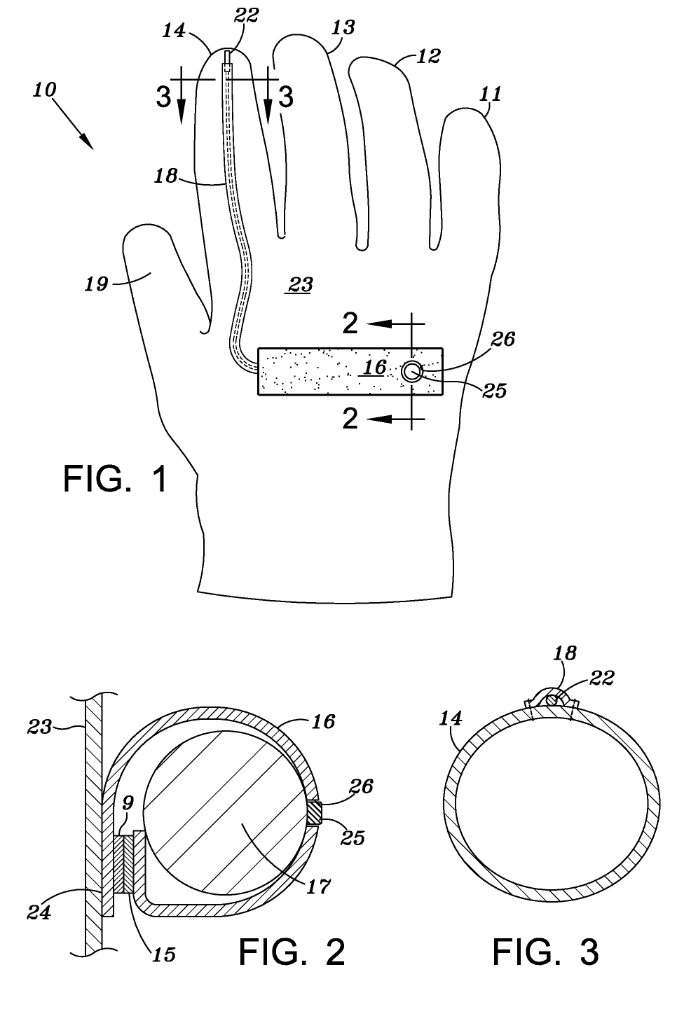

Referring to FIG. 1, a glove 10 according to an embodiment of the invention includes a top portion 23 including a thumb portion 19 and finger portions 14, 13, 12 and 11. A pocket 16 is formed by flexible piece or flap of material secured to the top of the glove for example by stitching at 24. One end of flap 16 has a first portion of a Velcro® type connector 9 and the other end of the flap has a second portion 15 of the Velcro® type connector, generally known as a hook and loop type connector. Other types of connectors such as zippers or snaps may also be used to form the pocket.

A non-contact voltage detector 17 such as disclosed in either U.S. Pat. No. 5,103,165 or in U.S. Pat. No. 5,877,618, for example, is held within pocket 16. The antenna or probe 18 of the detector is extended to run from the detector 17 to the end of a finger portion, for example, index finger tip 14. Flap 16 may include an aperture 26 to expose a light 25 of the detector which when lit would indicate the presence of a voltage. Detector 17 may also include an audible alarm.

Antenna or probe 22 of the detector may extend within a channel formed by a second piece of material 18 and sewn onto the top surface of finger portion 14 of the glove.

Glove 10 may be formed of any well-known glove material commonly used for work gloves such as leather, cotton, rubber or the like and may include an outer layer of leather, cotton or other fabric and an inner layer of insulation material such as natural and artificial rubber, foam and plastic materials.

In use, a worker merely puts on a glove according to the invention to serve as an alarm should the worker's hand come too close to a live voltage. The glove may also be used to test for the presence of voltage in power outlets located in homes or businesses.

Although the present invention has been described with respect to specific details, it is not intended that such details should be regarded as limitations on the scope of the invention, except to the extent that they are included in the accompanying claims.

1. A safety glove for detecting the presence of voltage in proximity to the glove comprising:
a) a glove;
b) a voltage detector attached to the glove; and
c) the voltage detector having an antenna or probe extending to a peripheral portion of the glove.

2. A safety glove as claimed in claim 1 further including a pocket formed on a top surface of the glove, the voltage detector being positioned within the pocket.

3. A safety glove as claimed in claim 2 further including a channel formed in the glove, the antenna or probe of the voltage detector extending within the channel.

4. A safety glove as claimed in claim 3 wherein the glove includes a plurality of finger portions, and the channel extends a tip portion of one of the finger portions.

5. A safety glove as claimed in claim 1 wherein the pocket includes an aperture for exposing an indicator light on the voltage detector.

6. A safety glove as claimed in claim 1 wherein the voltage detector is a non-contact type detector.

7. A safety glove as claimed in claim 1 wherein the pocket is formed by a flexible piece of material having one end connected to the glove and a second end rolled over and releasably attached to the first end.
